(19) United States
(12) Patent Application Publication
(10) Pub. No.: US 2020/0014360 A1
(43) Pub. Date: Jan. 9, 2020

(54) TUNABLE VARIABLE-INDUCTANCE FILTER

(71) Applicant: THALES, COURBEVOIE (FR)

(72) Inventors: Pierre GUERN, CHOLET (FR); Germain FOUGERAY, CHOLET (FR); Cédrick SABOUREAU, CHOLET (FR)

(21) Appl. No.: 16/465,088

(22) PCT Filed: Nov. 28, 2017
(86) PCT No.: PCT/EP2017/080711

§ 371 Date: May 29, 2019

(30) Foreign Application Priority Data
Nov. 29, 2016 (FR) 16/01686

(51) Int. Cl. H03H 7/01

(52) U.S. Cl. CPC H03H 7/0115; H03H 2210/012; H03H 7/0161; H03H 7/0123

(57) ABSTRACT

A tunable filter includes at least two tunable resonators, a resonator comprising at least one inductance or transmission line, the inductance or transmission line having a first end connected to the ground M and a second end coupled to another resonator via a coupling impedance, and several switched capacitors, wherein the inductance or transmission line comprises several access points or connection points distributed along the inductance allowing for the connection or non-connection of a switched capacitor whose value is defined as a function of its position on the inductance, the capacitors of low weights are situated close to the end of the inductance linked to the ground M. A use of the filter in radio transceivers is also provided.

The invention relates to a tunable filter with variable inductance. It is for example used for radio transceivers. It relates also to power filters, Very High Frequency, VHF, and Ultra High Frequency, UHF.

The cosite operation of radio transceivers generates a degradation in the operation of the radio stations, when they are in a situation of proximity between a transmitter and a receiver of another network, and this is because of the out-of-band noise emitted by the transmitter and/or the desensitization of a receiver by nearby transmitters. In the UHF range and a part of the VHF band, a channelling of fixed bandwidth and therefore cosite filters of pass bandwidth and rejection that are constant with the tuning frequency is sought. Now, the tunable filters “naturally” have a constant quality factor Q_{filter}. That means that the filter widens in proportion to the tuning frequency.

The topology of the tunable filters involves resonant elements consisting of fixed inductances or transmission lines (bars). The tuning is performed by means of variable capacitors placed in parallel to an end of the inductance or resonant bar. The problem is that the quality factor or the overvoltage of the filter is of the form:

Qfilter≅Central frequency/bandwidth

and

Qfilter≅Coupling impedance/internal impedance (Internalimpedance of the resonator at the central frequency.)

Since a constant bandwidth is required, the following is deduced therefrom:

Qfilter≅k′.Central frequency

Coupling impedance≅k′:Internal impedance.Central frequency

Since, in the conventional filter topology, the internal impedance of the filter is of the form Lω (fixed inductance) or Zₒ.tanθ(≅Zₒ.flfᵥ, for a short bar), the following is deduced therefrom:

Coupling impedance≅k″.(Central frequency)².

This is technically and physically difficult to produce, while observing the criterion of a good proportionality and therefore of a good constancy of the bandwidth of the filter over a wide central frequency tuning range.

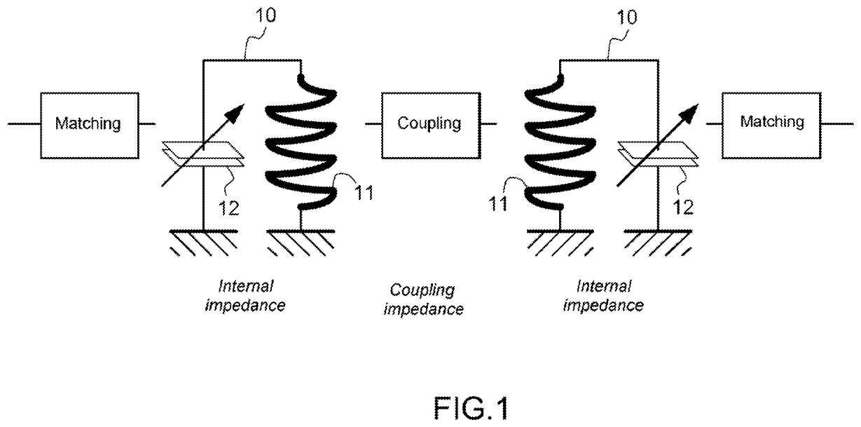

FIG. 1 illustrates a high power tunable filter according to the prior art. The filter comprises two resonators 10 consisting of bars or fixed inductances 11 tuned by a bank of switched capacitors 12.

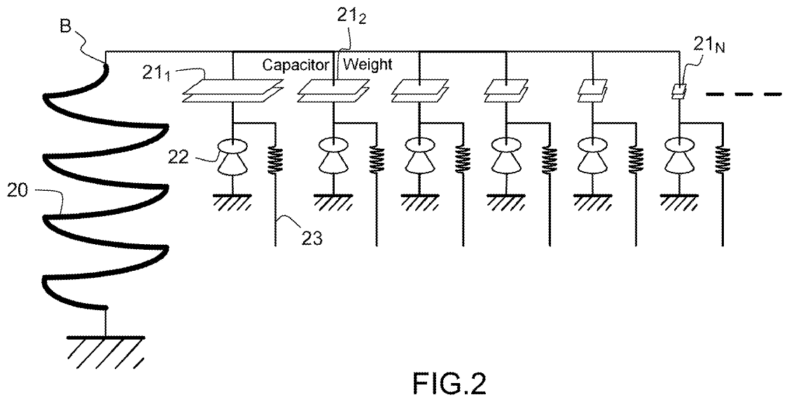

FIG. 2 illustrates a variant tunable filter, comprising an inductance of fixed (constant) value 20 and several fixed switched capacitors 21i. The fixed switched capacitors, having staged values, are all grouped together at the end of the bar or inductance at the point B and switched by diodes of PIN type 22 activated by a diode control 23. The value of the inductance is fixed and the internal impedance of the filter is proportional to the tuning frequency.

Despite the advantages that they provide, the filters according to the prior art merely approximate the filter response sought because of the complexity, even the impossibility, of synthesizing the necessary coupling impedance. Some filter topologies involve tunable filters for the coupling to the detriment of the losses of the filter.

There is therefore a need to have a filter exhibiting a pass bandwidth and a rejection band that are constant with the tuning frequency.

The method according to the invention consists, notably, in keeping the internal impedance of the filter constant or practically constant as a function of the tuning frequency F_{tuning} by means of fixed switched capacitors, the positions of which are distributed along the inductance forming the resonator and having variable values as a function of their position.

The invention relates to a tunable filter comprising at least two tunable resonators, a resonator comprising at least one inductance or transmission line, said inductance or transmission line having a first end connected to the ground M and a second end coupled to another resonator via a coupling impedance and several switched capacitors, characterized in that:
said impedance or transmission line comprises several access points or connection points distributed along said inductance allowing for the connection or non-connection of a switched capacitor whose value is defined as a function of its position on the inductance,
the capacitors of low weights belonging to the switched capacitors are situated close to the end of the inductance linked to the ground M,
the values of the capacitors and their positions on the inductance are defined so that the impedance of the resonator

$$\sqrt{\frac{{L}_{equi}}{{C}_{equi}}}$$

is kept constant throughout the tuning band of the tunable filter and the impedance of the resonator

$$\frac{1}{2 π \sqrt{\frac{1}{{L}_{equi} ⋆ {C}_{equi}}}}$$

is kept constant at the tunable frequency.

The number N of capacitors and the capacitor or capacitors to be activated are, for example, fixed as a function of the frequency variation pitch Of and of the range of operating frequencies [Fₘᵢₙ, Fₘₐₓ] of the filter.

The capacitors are, for example, linked to PIN diodes adapted to perform the switching thereof.

The position of the access points and the switched capacitor values can be chosen in order to obtain for the filter an internal impedance value at the centre frequency F_{c} seen by the filter at the second end of said inductance close to the coupling impedance that is quasi-constant.

The frequency band is the VHF band or the UHF band.

The filter according to the invention is used for example in a radio transceiver.

The invention relates also to a method implemented in a tunable filter according to the invention operating in a frequency range [Fₘᵢₙ, Fₘₐₓ] with a tuning frequency F_{tuning}, characterized in that:
the number N of capacitors and their position are defined as a function of the frequency range and the frequency pitch,
the number of capacitors to be switched is chosen in order to obtain a constant pass bandwidth and a constant rejection band with the tuning frequency.

Other features and advantages of the present invention will become more apparent on reading the description of exemplary embodiments given by way of illustration, with figures attached with represent:

FIG. 1, a first architecture of a tunable filter according to the prior art,

FIG. 2, the half of a tunable filter comprising a bank of switched capacitors, and

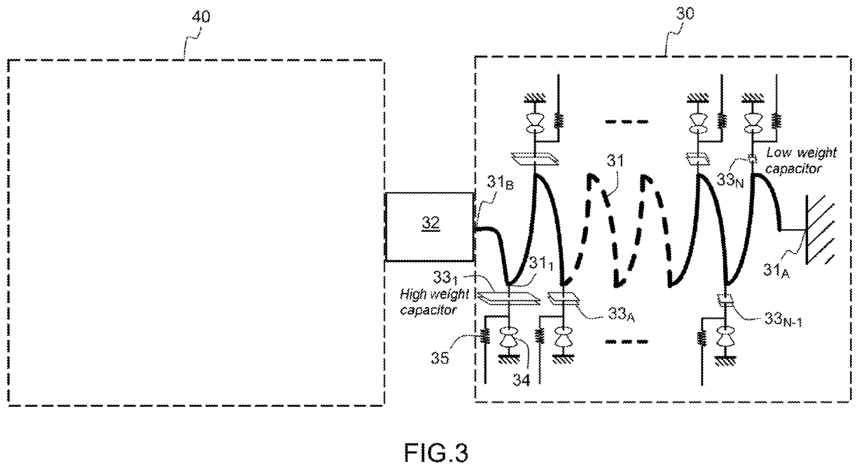

FIG. 3, an illustration of a filter according to the invention.

One of the aim of the present invention is to obtain a constant impedance

$$\sqrt{\frac{{L}_{equi}}{{C}_{equi}}}$$

at the tunable frequency

$$\frac{1}{2 π \sqrt{\frac{1}{{L}_{equi} ⋆ {C}_{equi}}}}$$

the values of the capacitors and their positions on the inductance are defined so that the impedance of the resonator

$$\sqrt{\frac{{L}_{equi}}{{C}_{equi}}}$$

is kept constant throughout the tuning band of the tunable filter and the impedance of the resonator

$$\frac{1}{2 π \sqrt{\frac{1}{{L}_{equi} ⋆ {C}_{equi}}}}$$

is kept constant at the tunable frequency. The problem is the ratio of the impedance of the resonator to the impedance of the coupling impedance, which will define the bandwidth of the desired bandpass filter. For this, small capacitor weights corresponding to high frequencies are physically associated with a low reactance value being closer to the end to ground. On the contrary, the capacitors of larger weights are very far from the mass in order to be put in parallel with an important self.

FIG. 3 illustrates an example of a filter according to the invention in which the capacitors are distributed along the inductance between a first end of the inductance linked to the ground and a second end linked to the rest of the filter.

The idea implemented is to electrically vary the value of the equivalent inductance, simultaneously with the switching of the capacitors weights (capacitors of variable values as a function of the position), in order to retain a passband value that is substantially constant and to vary the frequency according to a frequency plan [Fₘᵢₙ, Fₘₐₓ] defined by a given application. The frequency plan defines, for example, the different frequencies to be used and the frequency pitch ΔF with which the frequencies will be varied.

To construct the architecture of the filter according to the invention, the internal impedance will therefore be kept constant as a function of the tuning frequency F_{tuning} and, for that, the value of the inductance or the electrical length of the bar will be made variable with the frequency as follows:

low tuning frequencies−high equivalent inductance values,

high tuning frequencies−low equivalent inductance values.

FIG. 3 illustrates an example of architecture of the filter according to the invention, in which only one half-resonator element of the filter is detailed for reading simplicity, the filter operating in a frequency range [Fₘᵢₙ, Fₘₐₓ]. The symmetrical part of the filter, the second resonator 40, comprises elements identical to those described for the resonator 30 and will be deduced from the following description, without difficulty, by the person skilled in the art.

In FIG. 3, the resonator 30 comprises several switched capacitors which are distributed along the inductance 31. A first end 31_{A} of the inductance is coupled to the ground M. A second end 31_{B} is coupled, using a coupling impedance 32 as indicated in FIG. 1, to another resonator 40 not detailed for simplification. The inductance comprises several access points 31i or connection points distributed over its length, the access points being used for the connection of the switched capacitors which will be connected as a function of the desired values. The filter comprises, for example, N switched capacitors 33ᵢ controlled by a PIN diode 34 linked to an activation control 35.

A switched capacitor 33i is positioned at a point 31i of the inductance. This point can be identified by its distance di counted from one of the ends 31_{A}, 31_{B} of the inductance 31. In the example, the connection point of the capacitor is identified in relation to the second end 31_{B} of the inductance.

The switched capacitors are distributed along the inductance as follows: the capacitors of high weights, corresponding to the low tuning frequencies, therefore to an equivalent inductance value seen at the point 31_{B} that is high, are arranged further away from the ground than the capacitors at low weights, corresponding to the high frequencies which are arranged close to the ground towards the first end 31_{A} of the inductance.

The values of capacitors and their positions on the inductor are defined so that the impedance of the resonator is kept constant throughout the tuning band of the tunable filter. The impedance of the resonator

$$\sqrt{\frac{{L}_{equi}}{{C}_{equi}}}$$

is kept constant at the tunable frequency

$$\frac{1}{2 π \sqrt{\frac{1}{{L}_{equi} ⋆ {C}_{equi}}}}$$

The value of the equivalent inductance L_{equi} will vary electrically, by acting on the number of switched capacitors connected and the choice of their position along the inductance. The idea will be to connect some of the capacitors Cᵢ. By varying the value of the inductance and also the value of the total capacitance of the filter (corresponding to all the switched capacitors connected for a given configuration), it is possible to retain, for the filter, an impedance that is constant as a function of the tuning frequency and, thereby, a passband value that is constant for the filter.

The number N of switched capacitors is, for example, chosen as a function of the frequency pitch δf to scan in the frequency band [Fₘᵢₙ, Fₘₐₓ] for a given application.

The values and the position of the capacitors Cᵢ operated by switching are chosen as a function of the frequency values desired in the tuning band of the filter. The bank of capacitors is distributed over all the length of the inductance giving, by the switching of the capacitors, the equivalent of a frequency-variable inductance by variation of the electrical length.

The positioning, the distance dᵢ of a capacitor in relation to one of the ends of the inductance participates in the definition of the value of the inductance L. For example, by activating the capacitor 33₁, an inductance value L₁ is defined that is equal to the total value of the inductance−the inductance value corresponding to d₁. The number and the choice of the switched capacitors activated as a function of their placement on the inductance are a function for example of the frequency value to be obtained and of the desired frequency resolution.

As a first approximation, a constant impedance is required, which means that

$$\sqrt{\frac{Li}{Ci}}$$

must be constant and therefore that the inductance is proportional to the capacitance. The central frequency F_{c} of the filter will be proportional to

$$\sqrt{\frac{1}{LiCi}}$$

and therefore Cᵢ must be proportional to the inverse of the central frequency, as well as Lᵢ, which is the equivalent inductance value at the points 31_{B}.

The following numbered example is given to illustrate how to define the characteristics of the capacitors, by way of example. The result will be refined by simulation according to methods known to the person skilled in the art.

The number of switched capacitors is determined as a first approximation by df/f=resolution of the filter (at the highest frequency)=½^{N}, where N is the number of capacitors as a first approximation staged two by two in values. For example, if, at 500 MHz, a pitch of 0.5 MHz is sought, at least 1024 capacitors values are needed, i.e. 10 bit/10 distinct capacitors values staged two by two.

According to a first variant embodiment, an access point for a capacitor may be arranged every half-turn of the inductance when the latter is in the form of a coil.

The explanations which have been given apply to filters comprising a transmission line that is “short” compared to the wavelength λ/4, the line being able to be modelled by an induction coil for the low frequencies.

The tunable filter according to the present invention notably offers the following advantages:
a natural constant band response without approximation,
a constant of the response of the filter, passband and rejection band, with the tuning frequency,
a possibility of optimizing the filter, without compromise, over wide tuning bands.

The capacitors values and their spatial positions make it possible:

To cover important tuning range

$$\frac{1}{2 π \sqrt{\frac{1}{{L}_{equi} ⋆ {C}_{equi}}}}$$

may be greater than one octave for a power filter (having significant noise elements),
To maintain an impedance at a constant value throughout the tuning range, This makes it possible, with a simple inductive coupling between the resonators, to obtain an almost quasi constant filter in a wide tuning band.

1. A tunable filter comprising at least two tunable resonators, a resonator comprising at least one inductance or transmission line, said inductance or transmission line having a first end connected to the ground M and a second end coupled to another resonator via a coupling impedance, and several switched capacitors, wherein:
said inductance or transmission line comprises several access points or connection points distributed along said inductance allowing for the connection or non-connection of a switched capacitor whose value is defined as a function of its position on the inductance,
the capacitors of low weights belonging to the switched capacitors are situated close to the end of the inductance linked to the ground M,
the values of the capacitors and their positions on the inductance are defined so that the impedance of the resonator
$$\sqrt{\frac{{L}_{equi}}{{C}_{equi}}}$$
is kept constant throughout the tuning band of the tunable filter and the impedance of the resonator
$$\frac{1}{2 π \sqrt{\frac{1}{{L}_{equi} ⋆ {C}_{equi}}}}$$
is kept constant at the tunable frequency.

2. The tunable filter according to claim 1, wherein the number N of capacitors and the capacitor or capacitors to be activated is/are fixed as a function of the frequency variation pitch δf and of the operating range [Fₘᵢₙ, Fₘₐₓ].

3. The tunable filter according to claim 1, wherein it comprises a PIN diode linked to a switched capacitor, said diode being adapted to switch said switched capacitor on reception of a switching command.

4. The tunable filter according to claim 1, wherein the position of the access points and the switched capacitors values are chosen in order to obtain for the filter an internal impedance value at the central frequency F_{c} seen by the filter at the second end of said inductance close to the coupling impedance that is quasi-constant.

5. The tunable filter according to claim 1, wherein the operating frequency band is the Very High Frequency VHF band.

6. The tunable filter according to claim 1, wherein the operating frequency band is the Ultra High Frequency UHF band.

7. A radio transceiver, wherein it comprises one or more tunable filters according to claim 1.

8. The method implemented in a tunable filter operating in a frequency range [Fₘᵢₙ, Fₘₐₓ] with a tuning frequency F_{tuning} according to claim 1, wherein:
the number N of capacitors and their position are defined as a function of the frequency range and of the frequency pitch,
a number of capacitors to be switched is chosen in order to obtain a constant pass bandwidth and a constant rejection band with the tuning frequency.
